(19) United States
(12) Patent Application Publication
(10) Pub. No.: US 2025/0298084 A1
(43) Pub. Date: Sep. 25, 2025

(54) BATTERY INSPECTION METHOD

(71) Applicant: LG ENERGY SOLUTION, LTD., Seoul (KR)

(72) Inventors: Yeonhyuk HEO, Daejeon (KR); Kwanghyun KIM, Daejeon (KR); Byung Joon CHAE, Daejeon (KR); Kyun II RAH, Daejeon (KR)

(21) Appl. No.: 18/863,328

(22) PCT Filed: Dec. 15, 2023
(86) PCT No.: PCT/KR2023/095120

§ 371 Date: Nov. 5, 2024

(30) Foreign Application Priority Data
Dec. 15, 2022 (KR) 10-2022-0175754

(51) Int. Cl. G01R 31/389; G01R 31/36

(52) U.S. Cl. CPC G01R 31/389; G01R 31/3648

(57) ABSTRACT

Battery inspection methods are provided. The provided battery inspection methods include battery inspection methods which comprise: a data acquisition step of acquiring impedance spectrum data for a finished secondary battery in order to identify cracks in the electrodes of the secondary battery through non-destructive inspection; a first function acquisition step of acquiring a first function, having the log scale of the measurement frequency as an independent variable and the absolute value of impedance as a dependent variable, from the impedance spectrum data through function fitting; a second function acquisition step of acquiring a second function by differentiating the first function with respect to the log scale of the measurement frequency; and a battery state determination step of determining the state of the secondary battery on the basis of the second function.

### CROSS-REFERENCE TO RELATED APPLICATIONS

This application is a National Phase entry pursuant to 35 U.S.C. § 371 of International Application No. PCT/KR2023/095120 filed on Dec. 15, 2023, which claims priority to and the benefit of Korean Patent Application No. KR 10-2022-0175754, filed on Dec. 15, 2022. The contents of the above-identified applications are herein incorporated by reference in their entireties.

### TECHNICAL FIELD

The present disclosure relates to battery inspection methods, and relates to battery inspection methods which are capable of identifying cracks in electrodes of a completed secondary battery by non-destructive testing.

### BACKGROUND

After shipment of an initial cell, one of various phenomena that occur as a secondary battery degenerates due to progress of high-temperature storage, charge-discharge cycles, and the like, is occurrence of micro-cracks in electrodes.

It is important to identify the micro-cracks that occur in the electrodes because they can affect not only the performance and lifespan of the battery, but also its durability and safety. In addition, if the micro-cracks can be identified in a battery in use, it is possible to predict a maintenance cycle and future performance related to the battery, so analyzing them may serve as powerful data in battery operation.

Conventionally, as a technique for identifying cracks in the electrodes, it is possible to quantify the cracks in the electrodes by analyzing an electron microscope image of the electrodes. However, since analysis of the phenomenon of occurrence of cracks in the electrodes through electron microscopy is carried out by completely disassembling the battery and extracting the electrodes from the battery, there is a problem in that the battery in which the analysis has been performed should be discarded. In other words, it was not possible to monitor a state of occurrence of cracks of the electrodes of the battery during use by using the electron microscopy method.

In addition, since a process of preparing an analysis sample was cumbersome and measurement took a long time, the electron microscopy method had problems with its use as immediate feedback data.

Therefore, there is a need for a technology that can be applied to a battery in use as non-destructive analysis and that can perform analysis in a short period of time to immediately monitor the phenomenon of occurrence of cracks in electrodes of the battery.

The background description provided herein is for the purpose of generally presenting context of the disclosure. Unless otherwise indicated herein, the materials described in this section are not prior art to the claims in this application and are not admitted to be prior art, or suggestions of the prior art, by inclusion in this section.

### SUMMARY

The present disclosure relates to battery inspection methods, and an object of the present disclosure is to provide battery inspection methods which are capable of identifying cracks in electrodes of a completed secondary battery by non-destructive testing.

Technical objects to be accomplished by the present disclosure are not limited to the technical objects mentioned above, and other technical objects not mentioned may be clearly understood by those skilled in the art to which the present disclosure pertains from the following description.

A battery inspection method of the present disclosure may include: acquiring impedance spectral data for a secondary battery; fitting from the impedance spectral data, a first function using an input frequency as an independent variable and an absolute value of impedance as a dependent variable; differentiating the first function by the input frequency to acquire a second function; and determining a state of the secondary battery based on the second function.

In a battery inspection method of the present disclosure the impedance spectral data may be acquired by applying alternating current power to the secondary battery at the input frequency of 10⁻² Hz to 10⁵ Hz.

In a battery inspection method of the present disclosure the first function may be fitted using a first equation:

Z_{abs}=F₁(log f)

wherein Z_{abs} is the absolute value of the impedance, F₁ (log f) is the first function, and f is the input frequency.

In a battery inspection method of the present disclosure the second function may be of a form:

$${F}_{2} ( log f ) = \frac{d {Z}_{a b s}}{d log f}$$

wherein F₂(log f) is the second function.

In a battery inspection method of the present disclosure the state of the secondary battery may be determined based on the second function where a value of log f ranges from 0 to 1.

In a battery inspection method of the present disclosure when an inflection point exists in the second function where the value of log f ranges from 0 to 1, it may be determined that an electrode of the secondary battery is cracked.

The secondary battery inspected by a battery inspection method disclosed herein, may have no inflection point that exists in the second function where a value of log f ranges from 0 to 1.

According to a battery inspection method of the present disclosure, it is possible to identify cracks in electrodes of a completed secondary battery by non-destructive testing.

A battery inspection method of the present disclosure is applicable to a battery in use as non-destructive analysis, and it is possible to monitor the phenomenon of occurrence of cracks in the electrodes of the battery immediately by performing the analysis in a short time.

According to a battery inspection method of the present disclosure, it is possible to inspect a state of occurrence of micro-cracks in the electrodes of the battery in about seven (7) minutes without destroying the battery.

### BRIEF DESCRIPTION OF DRAWINGS

The accompanying drawings illustrate various embodiments of the present disclosure and together with the foregoing disclosure, serve to provide further understanding of the technical features of the present disclosure, and thus, the present disclosure is not construed as being limited to the drawings.

FIG. 1 is a block diagram illustrating a battery inspection method of the present disclosure.

FIG. 2 is a graph illustrating an imaginary part of impedance and a second function for a secondary battery of Example 1.

FIG. 3 is a graph illustrating an imaginary part of impedance and a second function for a secondary battery of Example 2.

FIG. 4 is a graph illustrating an imaginary part of impedance and a second function for a secondary battery of Example 3.

### DETAILED DESCRIPTION

A battery inspection method of the present disclosure may include:
a data acquisition step S10 of acquiring impedance spectral data for a secondary battery;
a first function acquisition step S20 of acquiring, through function fitting, a first function which uses a logarithmic scale of a measurement frequency as an independent variable and an absolute value of impedance as a dependent variable from the impedance spectral data;
a second function acquisition step S30 of acquiring a second function by differentiating the first function by the logarithmic scale of the measurement frequency; and
a battery state determination step S40 of determining a state of the secondary battery based on the second function.

In the data acquisition step S10 of the battery inspection method of the present disclosure, the impedance spectral data may be acquired by applying alternating current power to the secondary battery for a band of the measurement frequency including a band of 10⁻² Hz to 10⁵ Hz.

In the first function acquisition step S20 of the battery inspection method of the present disclosure, the first function may be acquired in the form of the following Equation 1.

$${Z}_{abs} = {F}_{1} ( log f ) \qquad Equation 1$$

Z_{abs} is the absolute value of the impedance, F₁(log f) is the first function, and f is the measurement frequency.

In the battery inspection method of the present disclosure, the second function may be acquired in the form of the following Equation 2.

$${F}_{2} ( log f ) = \frac{d {Z}_{a b s}}{d log f} \qquad Equation 2$$

F₂(log f) is the second function.

In the battery state determination step S40 of the battery inspection method of the present disclosure, the state of the secondary battery may be determined based on the second function in a range where the log f is 0 to 1.

In the battery state determination step S40 of the battery inspection method of the present disclosure, when an inflection point exists in the second function in the range where the log f is 0 to 1, it may be determined that cracks occur in electrodes of the secondary battery.

In the secondary battery measured by the battery inspection method of the present disclosure, no inflection point exists in the second function in the range where the log f is 0 to 1.

Hereinafter, embodiments according to the present disclosure will be described in detail with reference to the accompanying drawings. In this process, the size or shape of the components shown in the drawings may be exaggerated for clarity and convenience of explanation.

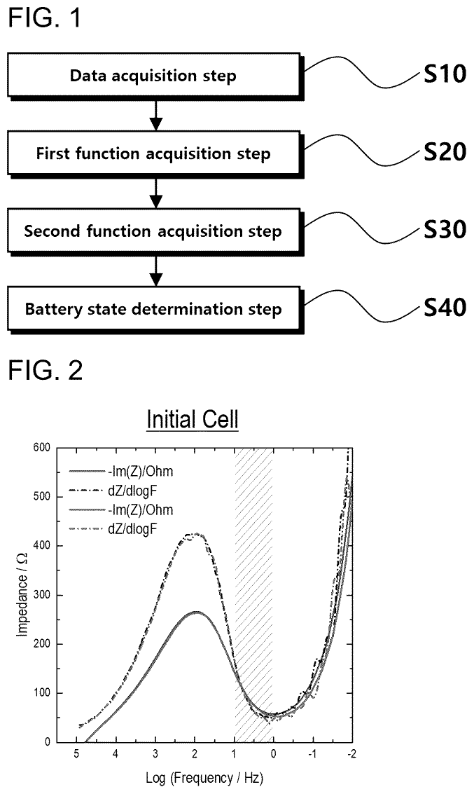

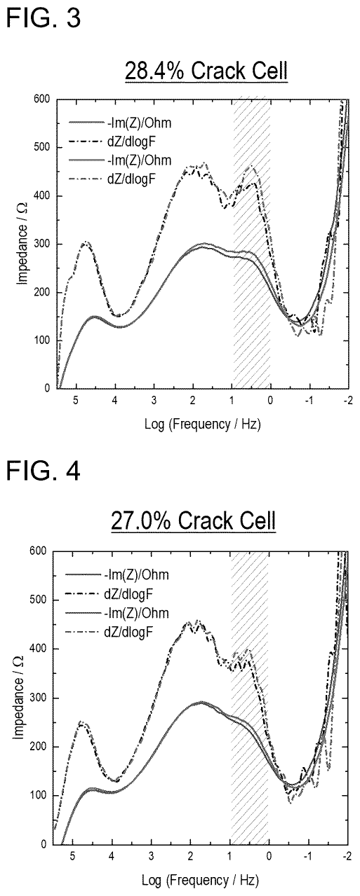

FIG. 1 is a block diagram illustrating a battery inspection method of the present disclosure. FIG. 2 is a graph illustrating an imaginary part of impedance and a second function for a secondary battery of Example 1. FIG. 3 is a graph illustrating an imaginary part of impedance and a second function for a secondary battery of Example 2. FIG. 4 is a graph illustrating an imaginary part of impedance and a second function for a secondary battery of Example 3.

Hereinafter, with reference to FIGS. 1 to 4, battery inspection methods of the present disclosure will be described in detail.

A battery inspection method of the present disclosure may non-destructively analyze whether cracks occur in electrodes accommodated within a secondary battery case without opening the case.

A secondary battery to be analyzed by a battery inspection method of the present disclosure may include an electrode manufactured by applying an electrode slurry to a metal substrate (a metal foil, etc.) and then drying it. The electrode slurry may be obtained by mixing an electrode active material, a conductive material, a binder, and a solvent and then kneading the mixture. The battery inspection method of the present disclosure may be able to determine whether a crack occurs in the dried electrode slurry.

As shown in FIG. 1, a battery inspection method of the present disclosure may include:
a data acquisition step S10 of acquiring impedance spectral data for a secondary battery;
a first function acquisition step S20 of acquiring, through function fitting, a first function which uses a logarithmic scale of a measurement frequency as an independent variable and an absolute value of impedance as a dependent variable from the impedance spectral data;
a second function acquisition step S30 of acquiring a second function by differentiating the first function by the logarithmic scale of the measurement frequency; and
a battery state determination step S40 of determining a state of the secondary battery based on the second function.

In the data acquisition step S10, the impedance spectral data may be acquired by electrochemical impedance spectroscopy (EIS). In other words, by applying alternating current power for a plurality of measurement frequencies and performing measurement with a voltmeter and an ammeter, an impedance value may be acquired for each of the plurality of measurement frequencies. In the data acquisition step S10 of the battery inspection method of the present disclosure, the impedance spectral data may be acquired by applying alternating current power to the secondary battery for a band of the measurement frequency including a band of 10⁻² Hz to 10⁵ Hz. More preferably, the impedance spectral data may be acquired by applying alternating current power to the secondary battery for a band of the measurement frequency including a band of 10⁰ Hz to 10¹ Hz.

The alternating current power may be applied by connecting negative and positive leads of the secondary battery to negative and positive terminals of a measurement and power supply device, respectively.

In the data acquisition step S10, the impedance value corresponding to each of the plurality of measurement frequencies may be acquired.

In the first function acquisition step S20, the first function may be acquired in the form of the following Equation 1.

$${Z}_{abs} = {F}_{1} ( log f ) \qquad Equation 1$$

Z_{abs} is an absolute value of the impedance, F₁ (log f) is the first function, and f is the measurement frequency.

The second function may be acquired in the form of the following Equation 2.

$${F}_{2} ( log f ) = \frac{d {Z}_{a b s}}{d log f} \qquad Equation 2$$

F₂ (log f) is the second function.

In the battery state determination step S40, the state of the secondary battery may be determined based on the second function in a range where the log f is 0 to 1. In other words, based on the impedance value at low frequency from 1 Hz to 10 Hz, the battery inspection method of the present disclosure may determine whether cracks occur in the electrodes of the battery.

In the battery state determination step S40, when an inflection point exists in the second function in the range where the log f is 0 to 1, it may be determined that cracks occured in the electrodes of the secondary battery. Therefore, the secondary battery in which there is no inflection point in the second function in the range where the log f is 0 to 1 may be determined to be a secondary battery in a normal state with no cracks in the electrodes.

### Example 1

For a secondary battery immediately after production, EIS was performed twice with measurement frequencies in the band of 10⁻² Hz to 10⁵ Hz, and two sets of impedance spectral data were acquired.

After calculating the absolute value for the impedance corresponding to each measurement frequency, the first function was acquired as a fitting function using the log scale of the measurement frequency as the independent variable and the absolute value of impedance as the dependent variable.

The acquired first function was differentiated by the logarithmic scale of the measurement frequency to acquire the second function.

### Example 2

For a secondary battery with 28.4% cracks formed in its electrodes, EIS was performed twice with measurement frequencies in the band of 10⁻² Hz to 10⁵ Hz to acquire two sets of impedance spectral data.

After calculating the absolute value for the impedance corresponding to each measurement frequency, the first function was acquired as a fitting function using the log scale of the measurement frequency as the independent variable and the absolute value of impedance as the dependent variable.

The acquired first function was differentiated by the logarithmic scale of the measurement frequency to acquire the second function.

### Example 3

For a secondary battery with 27.4% cracks formed in its electrodes, EIS was performed twice with measurement frequencies in the band of 10⁻² Hz to 10⁵ Hz to acquire two sets of impedance spectral data.

After calculating the absolute value for the impedance corresponding to each measurement frequency, the first function was acquired as a fitting function using the log scale of the measurement frequency as the independent variable and the absolute value of impedance as the dependent variable.

The acquired first function was differentiated by the logarithmic scale of the measurement frequency to acquire the second function.

In each of Examples 2 and 3, the crack % may be a value calculated by analyzing an image obtained by measuring with an electron microscope after destroying the battery after performing an electrode inspection method.

In each of FIGS. 2 to 4, the solid line is a graph for an imaginary part of the impedance, and the dashed line is a graph for the second function.

As shown in FIG. 2, the secondary battery in the normal state with no cracks has almost no curvature in the range where the log f is 0 to 1. As shown in FIGS. 3 and 4, it can be seen that the graph of the second function in each of FIGS. 3 and 4 includes an inflection point in the range where the log f is 0 to 1, while the graph of the imaginary part shows no significant change.

In other words, the battery inspection method of the present disclosure may determine with high sensitivity whether cracks occur in the electrodes of the battery through the second function. In addition, since measurement may only be performed in the range where the log f is 0 to 1, cracks may be identified in a short time.

Although the embodiments of the present disclosure have been described above, they are merely illustrative, and those skilled in the art will understand that various modifications and embodiments of an equivalent scope are possible therefrom. Accordingly, the true technical scope of protection of the present disclosure should be determined by the appended claims.

According to a battery inspection method of the present disclosure, it is possible to identify cracks in electrodes of a completed secondary battery by non-destructive testing.

Battery inspection methods of the present disclosure are applicable to a battery in use as non-destructive analysis, and it is possible to monitor the phenomenon of occurrence of cracks in the electrodes of the battery immediately by performing the analysis in a short time.

According to a battery inspection method of the present disclosure, it is possible to inspect a state of occurrence of micro-cracks in the electrodes of the battery in about seven (7) minutes without destroying the battery.

1. A battery inspection method comprising:
acquiring impedance spectral data for a secondary battery;
fitting from the impedance spectral data, a first function using an input frequency as an independent variable and an absolute value of impedance as a dependent variable;
differentiating the first function the input frequency to acquire a second function; and
determining a state of the secondary battery based on the second function.

2. The battery inspection method of claim 1, wherein the impedance spectral data is acquired by applying alternating current power to the secondary battery at the input frequency of 10⁻² Hz to 10⁵ Hz.

3. The battery inspection method of claim 1, wherein, in the first function is fitted using
$${Z}_{abs} = {F}_{1} ( log f ) \qquad Equation 1$$
wherein Z_{abs} is the absolute value of the impedance, F₁ (log f) is the first function, and f is the input frequency.

4. The battery inspection method of claim 3, wherein the second function is of a form:
$${F}_{2} ( log f ) = \frac{d {Z}_{a b s}}{d log f}$$
wherein F₂ (log f) is the second function.

5. The battery inspection method of claim 4, wherein the state of the secondary battery is determined based on the second function where a value of log f ranges from 0 to 1.

6. The battery inspection method of claim 5, wherein when an inflection point exists in the second function where the value of log f ranges from 0 to 1, it is determined that an electrodes of the secondary battery is cracked.

7. The secondary battery inspected by the battery inspection method of claim 4, wherein no inflection point exists in the second function where a value of log f ranges from 0 to 1.
